(19) United States
(12) Patent Application Publication
(10) Pub. No.: US 2006/0292839 A1
(43) Pub. Date: Dec. 28, 2006

(54) Contacts fabric using heterostructure of metal/semiconductor nanorods and fabrication method thereof

(76) Inventors: Gyu Chul Yi, Kyungangbuk-do (KR); Won Il Park, Kyungsangbuk-do (KR)

Correspondence Address: ROTHWELL, FIGG, ERNST & MANBECK, P.C., 1425 K STREET, N.W., SUITE 800, WASHINGTON, DC, 20005, US

(21) Appl. No.: 10/558,899

(22) PCT Filed: Feb. 24, 2004
(86) PCT No.: PCT/KR04/00374

§ 371 Date: Dec. 2, 2005

(30) Foreign Application Priority Data
Jun. 9, 2003 (KR) 10-2003-0036740

(51) Int. Cl. H01L 31/07; H01G 9/20; H01L 21/28

(52) U.S. Cl. 438/570; 438/497; 257/471

(57) ABSTRACT

Provided are a contact fabric using a heterostructure of metal/semiconductor nanorods and a method of manufacturing the same. An ohmic contact fabric having a low contact resistance or a Schottky contact fabric having a rectification characteristic is formed by selectively depositing metal of nano-sizes onto predetermined portions of zinc oxide/semiconductor nanorods and controlling the work function of the deposited metal and the interfacial characteristics of metal/zinc oxide. The contact fabric can be applied to various nano-sized electronic devices, including Schottky diodes, optical devices, and arrays thereof.

### CROSS REFERENCE TO RELATED APPLICATION

This application is a 35 U.S.C. §371 National Phase Entry Application from PCT/KR2004/000374, filed Feb. 24, 2004, and designating the U.S.

### BACKGROUND OF THE INVENTION

1. Field of the Invention

The present invention relates to a contact fabric using a heterostructure of metal/semiconductor nanorods and a method of manufacturing the same, and more particularly, to a contact fabric using a heterostructure of metal/semiconductor nanorods, wherein an ohmic contact fabric having a low contact resistance or a Schottky contact fabric having a rectification characteristic is formed by selectively depositing metal in a nanometer scale onto predetermined portions of zinc oxide/semiconductor nanorods and controlling the work function of the deposited metal and the interfacial characteristics of metal/zinc oxide in order to apply the contact fabric to various electronic devices, optical devices, and arrays thereof including Schottky diodes in a nanometer scale, and a method of manufacturing the same.

2. Description of the Related Art

The information and communication age of the 21^{st} century has come about due to the development of very large scale integrated circuits and semiconductor lasers based on a quantum effect, which was triggered by the striking development of semiconductor technology since the invention of transistors. As the size of semiconductor devices is reduced, conventional technologies from micro electronic engineering cannot be applied to further limit the design rule. For example, an optical etching method cannot be used to manufacture semiconductor devices with sizes less than tens of nanometers because of limits in its optical resolution. Also, this type of semiconductor devices cannot be manufactured by a method using X-rays or electronic beams, which is not suited for mass-production and is very expensive. Accordingly, a bottom-up method by which nano-size semiconductor devices can be manufactured to display desired functions at atomic or molecular level has been developed.

In order to manufacture a nano-device by the bottom-up method, a technology by which a nanostructure with desired functions can be realized using a single material is needed. In particular, a contact fabric corresponding to an electrode of the nano-device plays an important role of supplying energy required for operation. In addition, because the nano-device includes an ohmic contact fabric having a low contact resistance and a Schottky contact fabric having various rectification characteristics depending on the work function difference between a semiconductor and a metal and depending on characteristics of an interface of the semiconductor and the metal, so that a technology of controlling such characteristics is necessary. However, technologies of forming an artificial nano-contact fabric in a predetermined portion of a nano-device are not established, and technologies of controlling the characteristics of the nano-contact fabric have not been studied yet.

### SUMMARY OF THE INVENTION

The present invention provides a contact fabric using a heterostructure of metal/semiconductor nanorods, wherein an ohmic contact fabric having a low contact resistance or a Schottky contact fabric having a rectification characteristic is formed by selectively depositing metal of nano-sizes onto predetermined portions of zinc oxide/semiconductor nanorods and controlling the work function of the deposited metal and the interfacial characteristics of metal/zinc oxide in order to apply the contact fabric to various nano-sized electronic devices, including Schottky diodes, optical devices, and arrays thereof.

The present invention also provides a method of manufacturing a contact fabric using a heterostructure of metal/semiconductor nanorods, wherein an ohmic contact fabric having a low contact resistance or a Schottky contact fabric having a rectification characteristic is formed by selectively depositing metal of nano-sizes onto predetermined portions of zinc oxide/semiconductor nanorods and controlling the work function of the deposited metal and the interfacial characteristics of metal/zinc oxide in order to apply the contact fabric to various nano-sized electronic devices, including Schottky diodes, optical devices, and arrays thereof.

According to an aspect of the present invention, there is provided a contact fabric using a heterostructure of metal/semiconductor nanorods, the contact fabric comprising: semiconductor nanorods grown on a predetermined base material; and metal deposited on predetermined portions of the semiconductor nanorods, wherein there is a low contact resistance ohmic characteristic or a rectifying Schottky characteristic between the nanorods and the metal depending on characteristics of interfaces between the nanorods and the metal and depending on the difference between work functions.

According to specific embodiments of the present invention, the contact fabric may be used as a Schottky contact fabric or an ohmic contact fabric in a Schottky diode, a transistor, an optical detecting device, a light-emitting device, a sensor device, a nano-system, an integrated circuit, and an array circuit.

The nanorods and the contact fabric may have a diameter less than 500 nm. The semiconductor nanorods may include at least one material selected from the group consisting of zinc oxide, titanium oxide, GaN, Si, InP, InAs, GaAs, and an alloy thereof.

When the semiconductor nanorods are n-type semiconductors and form the Schottky contact fabric with the metal, the metal deposited on the semiconductor nanorods may include at least one material selected from the group consisting of Ni, Pt, Pd, Au, W, and silicide metals, including PtSi and NiSi, wherein each of the listed materials has a work function that is greater than the affinity of the semiconductor nanorods to electrons.

When the semiconductor nanorods are n-type semiconductors and form the ohmic contact fabric with the metal, the metal directly deposited on the semiconductor nanorods may include at least one material selected from the group consisting of Ti, Al, and In, which have a smaller work function than the work function of the semiconductor nanorods.

Au or Pt may be deposited on the metal. Thermal annealing may be performed at a temperature of less than 1,000° C. after the metal is deposited to improve the electrical characteristics of the contact fabric.

According to another aspect of the present invention, there is provided a method of fabricating a contact fabric using a heterostructure of metal/semiconductor nanorods, the method comprising: growing semiconductor nanorods on a predetermined base material vertically or in a direction; and depositing a metal onto predetermined portions of the semiconductor nanorods using a sputtering method or a thermal or e-beam evaporation method, wherein there is a low contact resistance ohmic characteristic or a rectifying Schottky characteristic between the nanorods and the metal depending on characteristics of interfaces between the nanorods and the metal and depending on the difference between work functions.

### BRIEF DESCRIPTION OF THE DRAWINGS

The above and other features and advantages of the present invention will become more apparent by describing in detail exemplary embodiments thereof with reference to the attached drawings in which:

FIG. 1 is a perspective view illustrating a contact fabric using a heterostructure of metal/semiconductor nanorods and a method of manufacturing the same according to the present invention;

FIG. 2 is a perspective view illustrating an array structure of a contact fabric using a heterostructure of metal/semiconductor nanorods according to the present invention;

FIG. 3 is a perspective view illustrating a current sensing atomic force microscopy (CSAFM) method, which is performed to examine the electric characteristic of a heterostructure of metal/semiconductor nanorods on which metal is deposited according to the present invention;

FIG. 4 is a graph illustrating the electric conductivity of zinc oxide/semiconductor nanorods on which metal is not deposited according to the present invention, which is measured using a probe on which gold is coated;

FIG. 5 is a graph illustrating the electric conductivity of a heterostructure of gold/zinc oxide nanorods wherein gold is deposited on the zinc oxide semiconductor nanorods according to the present invention, which is measured using a probe on which gold is coated; and

FIG. 6 is a graph illustrating the electric conductivity of a heterostructure of gold/titanium/zinc oxide nanorods according to the present invention, which is measured using a probe on which gold is coated, in which the heterostructure was manufactured by continuously depositing titanium and gold on zinc oxide nanorods and performing thermal annealing.

### DETAILED DESCRIPTION OF THE INVENTION

Embodiments of a contact fabric using a heterostructure of metal/semiconductor nanorods and a method of manufacturing the same according to the present invention will be described in detail with reference to the appended drawings. Detailed descriptions of known technologies or structures, which may make the subject matter of the invention ambiguous, will not be provided. The technical terms used throughout the specification, which are defined based on the functions of corresponding elements, may vary depending on the intention of a user or an operator or circumstances. Therefore, the technical terms should be defined based on the contexts of the specification.

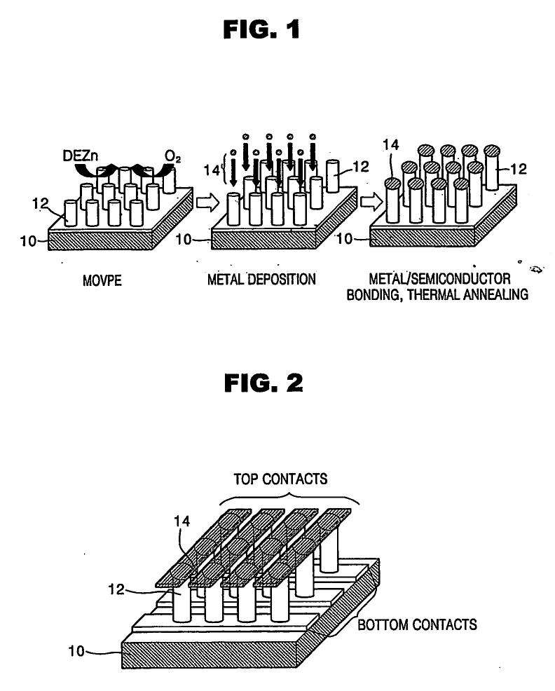

Referring to FIG. 1, a perspective view illustrating a contact fabric using a heterostructure of metal/semiconductor nanorods and the method of manufacturing the same is shown. In this case, zinc oxide/semiconductor nanorods 12 are grown on a material 10 in a direction or vertically using a metal organic vapor phase expitaxy (MOVPE) method. Then, metal 14′ is deposited on the nanorods 12 using a sputtering method or a thermal or e-beam evaporation method. Here, the metal 14′ is selectively deposited at the tips of the nanorods 12, resulting in forming a metal/semiconductor heterostructure having clear interfaces. In addition, various metals can be deposited at the tips of the nanorods 12. It is preferable that the diameters of the nanorods 12 and the metal deposited on the nanorods 12 be less than 500 nm. In addition, the electric characteristics of the interfaces may be controlled through an interfacial reaction occurring during thermal annealing. It is preferable that thermal annealing be performed at a temperature of lower than 1,000° C. Ohmic characteristic and Schottky characteristic may be controlled according to the kind of the deposited metal or the thermal annealing that will be described later.

FIG. 2 is a perspective view illustrating a highly integrated circuit using a heterostructure array of metal/semiconductor nanorods that is vertically grown on a large area. Here, contact fabrics are connected to the upper portions and the lower portions of the metal/semiconductor nanorods in order to control each of optical devices or nano-electronic devices.

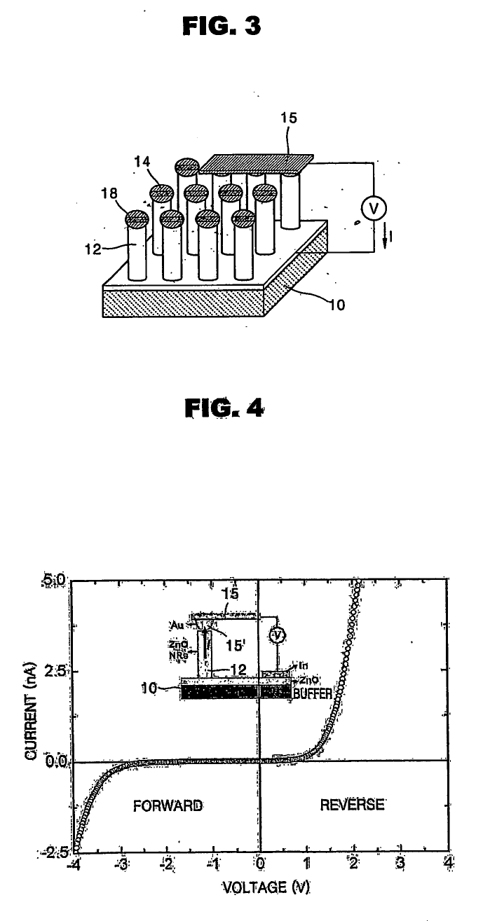

FIG. 3 is a perspective view illustrating a current sensing atomic force microscopy (CSAFM) method, which is performed to examine the electric characteristic of the heterostructure of metal/semiconductor nanorods shown in FIG. 1. Here, a probe 15 on which a metal is coated is placed on the tips of the heterostructure 12 or 14 of the metal/semiconductor nanorods, and the electric characteristic of each heterostructure of metal/zinc oxide nanorod is examined by using a lower layer 10 having an excellent conductivity. Reference numeral 18 denotes an AFM tip.

FIG. 4 is a graph illustrating the electric conductivity of a zinc oxide/semiconductor nanorod 12 on which a metal is not deposited, wherein the electric conductivity is examined by using a probe 15 on which gold is coated. Referring to the graph of FIG. 4, an unsymmetrical current-voltage (I-V) characteristic is shown due to a Schottky barrier, which is naturally formed by a bonding structure between a gold tip 15′ and a zinc oxide nanorod 12. However, a breakdown occurs under a low reverse voltage bias due to the very sharp gold tip 15′.

FIG. 5 is a graph illustrating the electric conductivity of a heterostructure of gold/zinc oxide nanorods, wherein gold 14 is deposited on the zinc oxide/semiconductor nanorods 12 and the electric conductivity is examined using a probe 15 as described with reference to FIG. 4. Referring to the graph of FIG. 5, a Schottky barrier is formed by a bonding structure between the deposited gold 14 and zinc oxide 12, resulting in a current-voltage (I-V) rectification characteristic. Specifically, an excellent Schottky characteristic in which a breakdown does not occur until about −8V is shown. The excellent Schottky characteristic can be shown because the work function of gold is large, so that another metal having a large work function can produce the excellent Schottky characteristic.

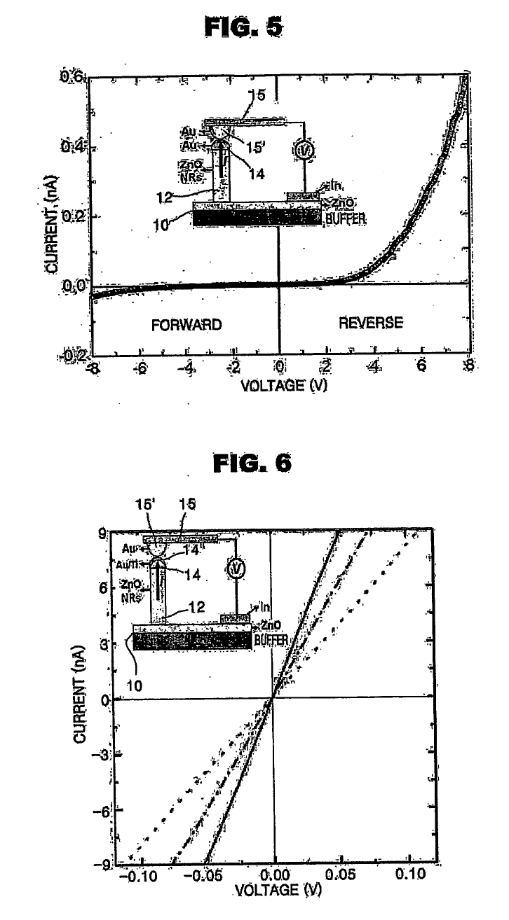

FIG. 6 is a graph illustrating the electric conductivity of a heterostructure of gold/titanium/zinc oxide nanorods, which is formed by continuously depositing titanium 14 and gold 14″ onto zinc oxide nanorods 12 and performing thermal annealing, wherein the electric conductivity is examined by using a probe 15 as described with reference to FIGS. 4 and 5. Referring to the graph of FIG. 6, a linear current-voltage (I-V) characteristic results from an ohmic contact fabric having a low contact resistance formed at the interface between titanium 14 and zinc oxide 12. The linear current-voltage (I-V) characteristic results because the work function of titanium is small and a tunneling effect increases due to the thermal annealing, resulting in the easy flow of currents. Accordingly, a metal having a small work function other than titanium can produce the linear current-voltage (I-V) characteristic.

In the present invention, a metal 14′ is deposited on semiconductor (zinc oxide) nanorods 12, which are grown on a material 10 vertically or in a direction, and thermal annealing is performed on the deposited metal 14′ to form a contact fabric 14 in a nanometer scale. In the case of the zinc oxide nanorods 12 having an n-type semiconductor, a Schottky contact fabric having a large energy barrier can be formed using Ni, Pt, Pd, Au, W, and silicide, such as PtSi and NiSi, that have as large work functions as Schottky contact fabric metal.

In addition, the ohmic contact fabric of the n-type zinc oxide nanorods 12 can be formed using Ti or Al having small work functions and lowering a contact resistance through an interfacial reaction. Alternatively, the contact fabric according to the present invention may be manufactured using various metals, including Cu, Ag, Mn, Fe, and Co.

Hereinafter, the present invention will be described in greater detail with reference to the following embodiments. The following embodiments are for illustrative purposes and are not intended to limit the scope of the invention.

### Embodiment 1

Growing of Metal/Zinc Oxide Nanorods (Refer to FIG. 1)

Gold and titanium/gold were deposited on commonly used zinc oxide/semiconductor nanorods arrayed in a direction using a thermal or e-beam evaporation method. Here, gold was deposited to a thickness of about 20 nm, and titanium/gold were deposited to thicknesses of 10 nm and 20 nm, respectively. The acceleration voltage and the emission current of the e-beam for evaporating metal were 4 to 20 kV and 40 to 400 mA, respectively. The pressure of a reactor was 10 to 5 mmHg when depositing metal, and the temperature of a base material was room temperature. The zinc oxide nanorods array was examined using an electro-microscope before and after the deposition of metal. As a result, it was found that the metal had been selectively deposited on the tips of the nanorods, and the diameters and the shapes of the nanorods were not significantly changed.

Measurement of Electrical Characteristics of Metal/Zinc Oxide Nanorods (Refer to FIGS. 4 Through 6)

The electric characteristics of the heterostructure of metal/zinc oxide nanorods were measured using current sensing atomic force microscopy (CSAFM). In particular, the heterostructure array of the metal/zinc oxide nanorods was scanned using a probe on which gold is coated, in order to determine the locations of the individual nanorods. In order to obtain AFM images, an elastic coefficient of 0.12N/m was applied when scanning the heterostructure array. When measuring the current-voltage (I-V) characteristic, a voltage was applied across the tip and the underlying zinc oxide conductive layer. This experiment was performed at room temperature, and the I-V curve was obtained over 20 times of repeating.

In order to examine changes in electric characteristics after the deposition of metal on the zinc oxide nanorods, I-V characteristics were measured using zinc oxide nanorods, a heterostructure of gold/zinc oxide nanorods, and a heterostructure of gold/titanium/zinc oxide nanorods under the same conditions. In addition, 20 to 40 nN was applied to the tip when measuring the I-V characteristics.

Referring to the graph of FIG. 4 illustrating the I-V curve of the zinc oxide nanorods on which metal is not deposited, a forward current flow is smooth due to the Schottky barrier formed by a bonding structure between gold tips and zinc oxide, but a reverse current flow is not smooth, resulting in unsymmetrical I-V characteristics. However, a breakdown occurs at a low reverse voltage bias due to the sharpness of gold tips.

On the other hand, in the case of the heterostructure of the gold/zinc oxide nanorods on which gold is deposited, the Schottky barrier is formed due to the bonding structure between gold and zinc oxide; however, a breakdown at a low reverse voltage bias can be suppressed due to a high electric field created on the gold tips, because the metal/semiconductor bonding is formed between zinc oxide and the gold layer deposited on the zinc oxide nanorods. Referring to the graph of FIG. 5, the Schottky characteristic is improved such that a breakdown can be suppressed even at about 8V. A similar Schottky contact fabric can be formed using Ni, Pt, Pd, W, and silicide such as PtSi and NiSi having large work functions.

The ohmic contact fabric having a low contact resistance plays an important role in supplying energy required to operate a device. In order to make such an ohmic contact fabric, in an embodiment, titanium and gold were sequentially deposited on the zinc oxide nanorods, and rapid thermal annealing was performed at a temperature of 300 to 500° C. Referring to the graph of FIG. 6, a linear I-V curve for a typical ohmic contact fabric was obtained, and current flow was greatly increased due to a low contact resistance. The ohmic contact fabric can be formed using In, Ti/Al, and Al/Au that can reduce contact resistance through an interface reaction.

According to the present invention, an ohimc contact fabric having a low contact resistance or a Schottky contact fabric illustrating a rectification characteristic can be formed by forming a metal contact fabric in a nanometer scale at predetermined portions of zinc oxide nanorods and controlling the electric characteristics of the metal contact fabric. Particularly, the technologies described in the present invention can be used to develop functional nanostructures which satisfy desired functions. In addition, the present invention can be used for developing electronic devices using vertically arranged nano-materials and highly integrated circuits using optical device arrays.

On the other hand, the present invention can form an ohmic contact fabric having a low contact resistance or a Schottky contact fabric having a rectification characteristic by selectively depositing metal in a nanometer scale onto predetermined portions of zinc oxide/semiconductor nanorods and controlling the work function of the deposited metal and the interfacial characteristic between metal and zinc oxide. In addition, the contact fabric can be applied to various electronic devices, optical devices, and arrays thereof that include Schottky diodes in a nanometer scale.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A contact fabric using a heterostructure of metal/semiconductor nanorods, the contact fabric comprising:
semiconductor nanorods grown on a predetermined base material; and
metal deposited on predetermined portions of the semiconductor nanorods,
wherein there is a low contact resistance ohmic characteristic or a rectifying Schottky characteristic between the nanorods and the metal depending on characteristics of interfaces between the nanorods and the metal and depending on the difference between work functions.

2. The contact fabric of claim 1, being used as a Schottky contact fabric or an ohmic contact fabric in a Schottky diode, a transistor, an optical detecting device, a light-emitting device, a sensor device, a nano-system, an integrated circuit, and an array circuit.

3. The contact fabric of claim 1, wherein the nanorods and the contact fabric have a diameter less than 500 nm.

4. The contact fabric of claim 1, wherein the semiconductor nanorods include at least one material selected from the group consisting of zinc oxide, titanium oxide, GaN, Si, InP, InAs, GaAs, and an alloy thereof.

5. The contact fabric of claim 2, wherein when the semiconductor nanorods are n-type semiconductors and form the Schottky contact fabric with the metal, the metal deposited on the semiconductor nanorods includes at least one material selected from the group consisting of Ni, Pt, Pd, Au, W, and silicide metals, including PtSi and NiSi, wherein each of the listed materials has a work function that is greater than the affinity of the semiconductor nanorods to electrons.

6. The contact fabric of claim 2, wherein when the semiconductor nanorods are n-type semiconductors and form the ohmic contact fabric with the metal, the metal directly deposited on the semiconductor nanorods includes at least one material selected from the group consisting of Ti, Al, and In, which have a smaller work function than the work function of the semiconductor nanorods.

7. The contact fabric of claim 6, wherein Au or Pt is deposited on the metal.

8. The contact fabric of claim 5, wherein thermal annealing is performed at a temperature of less than 1,000° C. after the metal is deposited to improve the electrical characteristics of the contact fabric.

9. A method of fabricating a contact fabric using a heterostructure of metal/semiconductor nanorods, the method comprising:
growing semiconductor nanorods on a predetermined base material vertically or in a direction; and
depositing a metal onto predetermined portions of the semiconductor nanorods using a sputtering method or a thermal or e-beam evaporation method,
wherein there is a low contact resistance ohmic characteristic or a rectifying Schottky characteristic between the nanorods and the metal depending on characteristics of interfaces between the nanorods and the metal and depending on the difference between work functions.

10. The method of claim 9, wherein the grown nanorods and the deposited contact fabric have a diameter less than 500 nm.

11. The method of claim 9, wherein the semiconductor nanorods include at least one material selected from the group consisting of zinc oxide, titanium oxide, GaN, Si, InP, InAs, GaAs, and an alloy thereof.

12. The method of claim 9, wherein when the semiconductor nanorods are n-type semiconductors and form a Schottky contact fabric with the metal, the metal deposited on the semiconductor nanorods includes at least one material selected from the group consisting of Ni, Pt, Pd, Au, W, and silicide metals, including PtSi and NiSi, wherein each of the materials has a work function that is greater than the affinity of the semiconductor nanorods to electrons.

13. The method of claim 9, wherein when the semiconductor nanorods are n-type semiconductors and form an ohmic contact fabric with the metal, the metal directly deposited on the semiconductor nanorods includes at least one material selected from the group consisting of Ti, Al, and In, which have a smaller work function than the work function of the semiconductor nanorods.

14. The method of claim 13, further comprising depositing Au or Pt onto the metal.

15. The method of claim 12, further comprising performing thermal annealing at a temperature of less than 1,000° C. after the metal is deposited to improve the electrical characteristics of the contact fabric.
